(19) United States
(12) Patent Application Publication
(10) Pub. No.: US 2026/0150634 A1
(43) Pub. Date: May 28, 2026

(54) HARD MASK STRUCTURE FOR INTEGRATED CIRCUIT MANUFACTURING, AND METHOD FOR MANUFACTURING INTEGRATED CIRCUIT DEVICE

(71) Applicant: INSTITUTE OF MICROELECTRONICS, CHINESE ACADEMY OF SCIENCES, Beijing (CN)

(72) Inventors: Tao YANG, Beijing (CN); Junjie LI, Beijing (CN); Xiaobin HE, Beijing (CN); Jianfeng GAO, Beijing (CN); Yayi WEI, Beijing (CN); Bowei DAI, Beijing (CN); Wenwu WANG, Beijing (CN)

(21) Appl. No.: 19/122,653

(22) PCT Filed: Oct. 26, 2022
(86) PCT No.: PCT/CN2022/127555

§ 371 Date: Apr. 18, 2025

(30) Foreign Application Priority Data
Oct. 21, 2022 (CN) 202211298888.2

(51) Int. Cl. H10P 76/40; H10P 50/00; H10P 50/26

(52) U.S. Cl. CPC H10P 76/405; H10P 50/266; H10P 50/71

(57) ABSTRACT

The present disclosure provides a hard mask structure for integrated circuit manufacturing and a method for manufacturing an integrated circuit device, which relate to a field of pattern transfer technology in a chip manufacturing process. The hard mask structure includes a first hard mask layer and a second hard mask layer stacked from top to bottom, where the first hard mask layer is used to form a noble metal on a surface thereof and used as a pattern-transfer sacrificial layer, and the second hard mask layer is used as a protective layer and used to etch a pattern-transfer target material; the first hard mask layer and the second hard mask layer are made of different materials and are resistant to a corrosion of a strong oxidizing chemical liquid applied for removing the noble metal; the second hard mask layer is resistant to a corrosion of a chemical liquid applied for removing the first hard mask layer by wet corrosion, and the second hard mask layer has a predetermined corrosion rate selectivity ratio to the first hard mask layer. The present disclosure may avoid damage of noble metal ions to devices, so that noble metal films may be applied to large-scale integrated circuit manufacturing.

### TECHNICAL FIELD

The present disclosure relates to a field of pattern transfer technology in a chip manufacturing process, and in particular to a hard mask structure for integrated circuit manufacturing and a method for manufacturing an integrated circuit device.

### BACKGROUND

Noble metals exhibit excellent chemical stability and do not produce distortion during pattern transfer, especially for fine patterns. Therefore, a noble metal film is an ideal hard mask material for pattern transfer.

However, noble metal ions may damage performance of integrated circuit devices, and thus noble metals are not used in a field of integrated circuit manufacturing. Currently, noble metals are used as hard masks only in a field of chip manufacturing that is insensitive to noble metal ions, such as manufacturing of non-volatile magnetic random access memory (MRAM).

### SUMMARY

In view of the above problems, the present disclosure provides a hard mask structure for integrated circuit manufacturing and a method for manufacturing an integrated circuit device, so that noble metal films may be applied to large-scale integrated circuit manufacturing.

In an aspect, the present disclosure provides a hard mask structure for integrated circuit manufacturing, including a first hard mask layer and a second hard mask layer stacked from top to bottom, where: the first hard mask layer is configured to form a noble metal on a surface thereof and configured as a pattern-transfer sacrificial layer, and the second hard mask layer is configured as a protective layer and configured to etch a pattern-transfer target material; the first hard mask layer and the second hard mask layer are made of different materials and are resistant to a corrosion of a strong oxidizing chemical liquid applied for removing the noble metal; the second hard mask layer is resistant to a corrosion of a chemical liquid applied for removing the first hard mask layer by wet corrosion, and the second hard mask layer has a predetermined corrosion rate selectivity ratio to the first hard mask layer; and the noble metal includes one or a combination of thin films selected from gold, silver, ruthenium, rhodium, palladium, osmium, iridium, or platinum.

Optionally, the first hard mask layer and the second hard mask layer constitute a dual hard mask set, and the hard mask structure includes a plurality of dual hard mask sets stacked in sequence.

Optionally, the first hard mask layer is made of a non-metallic dielectric material selected from at least one of silicon, silicon oxide, silicon nitride, polysilicon, amorphous silicon, silicon oxynitride, boron or phosphorus doped silicon oxide, silicon carbide, gallium nitride, indium phosphide, aluminum oxide, or titanium nitride; or the first hard mask layer is made of an organic material selected from a spin-on carbon film, an amorphous carbon film, a silicon-rich anti-reflective layer, or a carbon-rich anti-reflective layer.

Optionally, the second hard mask layer is made of a non-metallic dielectric material selected from at least one of silicon, silicon oxide, silicon nitride, polysilicon, amorphous silicon, silicon oxynitride, boron or phosphorus doped silicon oxide, silicon carbide, gallium nitride, indium phosphide, aluminum oxide, or titanium nitride; or the second hard mask layer is made of an organic material selected from a spin-on carbon film, an amorphous carbon film, a silicon-rich anti-reflective layer, or a carbon-rich anti-reflective layer.

Optionally, the strong oxidizing chemical liquid includes aqua regia; or the strong oxidizing chemical liquid contains high-purity HCl, high-purity HNO₃, and H₂O in a ratio of (0˜1):(0˜1):(0˜1).

Optionally, the first hard mask layer and the second hard mask layer are a combination of two thin films made of different materials, selected from: the first hard mask layer being made of Si₃N₄ and the second hard mask layer being made of SiO₂; the first hard mask layer being a silicon-rich anti-reflective layer and the second hard mask layer being a spin-on carbon film; or the first hard mask layer being made of polysilicon and the second hard mask layer being made of SiO₂.

In another aspect, the present disclosure provides a method for manufacturing an integrated circuit device using the hard mask structure for integrated circuit manufacturing as described above, including: forming a second hard mask layer, a first hard mask layer and a noble metal layer sequentially on a pattern-transfer target material, coating a photoresist on a surface of the noble metal layer, and performing photolithography to form a mask pattern; performing ion beam etching on the noble metal layer, and performing ion beam etching or reactive ion etching on the first hard mask layer, so as to transfer the mask pattern to a surface of the second hard mask layer; removing the noble metal layer by corrosion, and performing ion beam etching or reactive ion etching on the second hard mask layer, so as to transfer the mask pattern to a surface of the pattern-transfer target material; removing the first hard mask layer by corrosion, and etching the pattern-transfer target material according to the mask pattern; and removing the second hard mask layer by corrosion, and cleaning an etched product to obtain a desired integrated circuit device.

Optionally, the method for manufacturing the integrated circuit device further includes: after performing the reactive ion etching on the first hard mask layer, removing the photoresist.

Optionally, the removing the first hard mask layer by corrosion includes any selected from: removing the first hard mask layer by corrosion with H₃PO₄ at 160° C. in a case that the first hard mask layer is made of Si₃N₄ and the second hard mask layer is made of SiO₂; removing the first hard mask layer by corrosion with diluted hydrogen fluoride at room temperature in a case that the first hard mask layer is a silicon-rich anti-reflective layer and the second hard mask layer is a spin-on carbon film, or removing the first hard mask layer by corrosion with tetramethylammonium hydroxide at room temperature in a case that the first hard mask layer is made of polysilicon and the second hard mask layer is made of SiO₂.

Optionally, a corrosion rate is less than 1 nm/min in a process of removing the first hard mask layer by corrosion.

Compared with the prior art, the hard mask structure for integrated circuit manufacturing and the method for manufacturing the integrated circuit device provided by the present disclosure have at least following beneficial effects.
(1) The damage of noble metal ions to devices may be avoided, so that noble metal films may be applied to large-scale integrated circuit manufacturing.
(2) While ensuring an accurate pattern transfer, the dual hard mask structure is resistant to a corrosion of a strong oxidizing chemical liquid applied to remove the noble metal, that is, a dual hard mask material remains intact without morphological deformation during wet corrosion with strong acid. The dual hard mask structure composed of at least two layers of different materials may protect the pattern-transfer target material from contamination by noble metal ions.

### BRIEF DESCRIPTION OF THE DRAWINGS

The above and other objectives, features and advantages of the present disclosure will become more apparent through the following description of embodiments of the present disclosure with reference to the accompanying drawings, in which:

FIG. 1 schematically shows a process flow diagram of a hard mask structure for integrated circuit manufacturing according to embodiments of the present disclosure, and

FIG. 2 schematically shows a flowchart of a method for manufacturing an integrated circuit device according to embodiments of the present disclosure.

### DESCRIPTION OF REFERENCE NUMERALS

1—pattern-transfer target material; 2—second hard mask layer; 3—first hard mask layer; 4—noble metal layer; 5—photoresist; 6—mask pattern.

### DETAILED DESCRIPTION OF EMBODIMENTS

In order to make objectives, technical solutions and advantages of the present disclosure more clearly understood, the present disclosure will be further described in detail below in combination with specific embodiments and with reference to the accompanying drawings. Obviously, the described embodiments are merely some embodiments rather than all embodiments of the present disclosure. Based on embodiments of the present disclosure, all additional embodiments obtained by those ordinary skilled in the art without carrying out inventive effort fall within the scope of protection of the present disclosure.

Terms are used herein for the purpose of describing specific embodiments only and are not intended to limit the present disclosure. The terms “including”, “containing”, etc. used herein indicate the presence of the feature, step, operation and/or component, but do not exclude the presence or addition of one or more other features, steps, operations or components.

All terms (including technical and scientific terms) used herein have the meanings generally understood by those skilled in the art, unless otherwise defined. It should be noted that the terms used herein shall be interpreted to have meanings consistent with the context of this specification, and shall not be interpreted in an idealized or overly rigid manner.

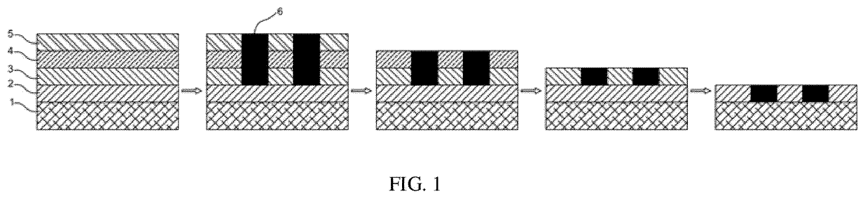

FIG. 1 schematically shows a process flow diagram of a hard mask structure for integrated circuit manufacturing according to embodiments of the present disclosure.

Referring to FIG. 1, embodiments of the present disclosure provide a hard mask structure for integrated circuit manufacturing, including a first hard mask layer 3 and a second hard mask layer 2 stacked from top to bottom.

The first hard mask layer 3 is used to form a noble metal 4 on a surface thereof and used as a pattern-transfer sacrificial layer. The noble metal includes one or a combination of thin films selected from gold, silver, ruthenium, rhodium, palladium, osmium, iridium, or platinum. The second hard mask layer 2 is used as a protective layer and used to etch a pattern-transfer target material 1.

The first hard mask layer 3 and the second hard mask layer 2 are made of different materials and are both resistant to a corrosion of a strong oxidizing chemical liquid applied for removing the noble metal.

The second hard mask layer 2 is resistant to a corrosion of a chemical liquid applied for removing the first hard mask layer 3 by wet corrosion, and the second hard mask layer 2 has a predetermined corrosion rate selectivity ratio to the first hard mask layer 3.

Through the above-mentioned structure, the hard mask structure may avoid a damage of noble metal ions to devices, so that noble metal films may be applied to large-scale integrated circuit manufacturing. Moreover, while ensuring an accurate pattern transfer, the hard mask structure is resistant to a corrosion of a strong oxidizing chemical liquid applied to remove the noble metal, that is, a dual hard mask material remains intact without morphological deformation during wet corrosion with strong acid. The dual hard mask structure composed of at least two layers of different materials may protect the pattern-transfer target material from contamination by noble metal ions.

It should be noted that the corrosion rate selectivity ratio may be specifically set according to actual needs, as long as the second hard mask layer 2 has a high corrosion rate selectivity ratio to the first hard mask layer 3.

In embodiments of the present disclosure, the first hard mask layer 3 and the second hard mask layer 2 constitute a dual hard mask set, and the hard mask structure includes a plurality of dual hard mask sets stacked in sequence. Therefore, the hard mask structure is composed of at least two layers of different materials, both of which are resistant to the corrosion of the strong oxidizing chemical liquid. Depending on pattern transfer requirements, film layers of different materials may be added based on the above-mentioned principles to form a three-layer or four-layer dual hard mask structure.

In embodiments of the present disclosure, the first hard mask layer 3 may be made of a non-metallic dielectric material, including but not limited to at least one of silicon, silicon oxide, silicon nitride, polysilicon, amorphous silicon, silicon oxynitride, boron (B) or phosphorus (P) doped silicon oxide, silicon carbide, gallium nitride, indium phosphide, aluminum oxide, or titanium nitride. Alternatively, the first hard mask layer 3 may be made of an organic material, including but not limited to a spin-on carbon (SOC) film, an amorphous carbon film, a silicon-rich anti-reflective layer (SiBACR), or a carbon-rich anti-reflective layer (BARC).

The first hard mask layer 3 and the second hard mask layer 2 are made of different materials. On this basis, the second hard mask layer 2 may be made of a non-metallic dielectric material, including but not limited to at least one of silicon, silicon oxide, silicon nitride, polysilicon, amorphous silicon, silicon oxynitride, boron (B) or phosphorus (P) doped silicon oxide, silicon carbide, gallium nitride, indium phosphide, aluminum oxide, or titanium nitride. Alternatively, the second hard mask layer 2 may be made of an organic material, including but not limited to a spin-on carbon (SOC) film, an amorphous carbon film, a silicon-rich anti-reflective layer (SiBACR), or a carbon-rich anti-reflective layer (BARC).

In embodiments of the present disclosure, the strong oxidizing chemical liquid includes aqua regia; or the strong oxidizing chemical liquid contains high-purity hydrochloric acid (HCl), high-purity nitric acid (HNO₃), and water (H₂O) in a ratio of (0˜1):(0˜1):(0˜1).

Accordingly, the strong oxidizing chemical liquid applied for removing the noble metal is primarily an aqua-regia-like liquid, in which the ratio of high-purity HCl, high-purity HNO₃ and H₂O is (0˜1):(0˜1):(0˜1). Furthermore, both the first hard mask layer 3 and the second hard mask layer 2 are resistant to the aqua-regia-like strong oxidizing chemical liquid, and a corrosion rate is less than 1 nm/min.

In embodiments of the present disclosure, the first hard mask layer 3 and the second hard mask layer 2 are a combination of two thin films made of different materials, selected from: the first hard mask layer 3 being made of Si₃N₄ and the second hard mask layer 2 being made of SiO₂; the first hard mask layer 3 being a silicon-rich anti-reflective layer (SiBACR) and the second hard mask layer 2 being a spin-on carbon (SOC) film; or the first hard mask layer 3 being made of Poly Si (polysilicon) and the second hard mask layer 2 being made of SiO₂.

Based on the above disclosure, the first hard mask layer 3 is used as a pattern-transfer sacrificial layer. After forming the mask pattern with the noble metal, the noble metal layer is removed. Subsequently, the first hard mask layer 3 is used to transfer the pattern to the second hard mask layer 2, and then the first hard mask layer 3 is removed, thereby avoiding residual noble metal ions in the first hard mask layer 3 and reducing a trace amount of noble metal ions on a wafer surface to an applicable level. In this process, the second hard mask layer 2 functions as a protective layer to protect the pattern-transfer target material from corrosion by the strong oxidizing chemical liquid applied to remove the noble metal, and to protect a surface of the pattern-transfer target material from contamination by noble metal ions.

After the above-mentioned process is completed, the pattern-transfer target material is etched using the second hard mask layer 2. After that, the second hard mask layer 2 is removed to obtain a final desired fine pattern.

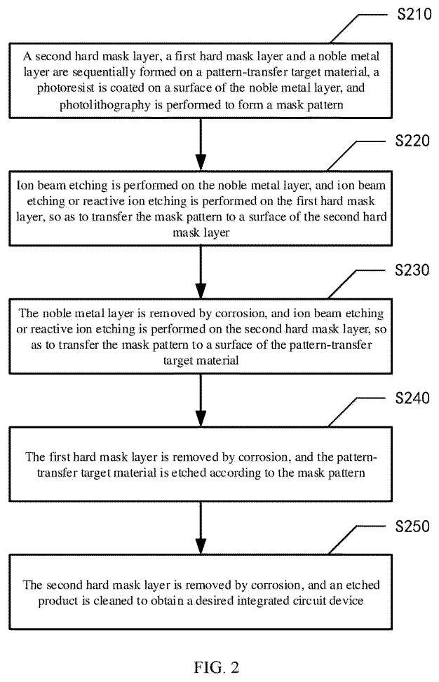

FIG. 2 schematically shows a flowchart of a method for manufacturing an integrated circuit device according to embodiments of the present disclosure.

Referring to FIG. 1 and FIG. 2, the method for manufacturing the integrated circuit device according to the embodiments may include operation S210 to operation S250.

In operation S210, a second hard mask layer 2, a first hard mask layer 3 and a noble metal layer 4 are sequentially formed on a pattern-transfer target material, a photoresist 5 is coated on a surface of the noble metal layer 4, and photolithography is performed to form a mask pattern.

In operation S220, ion beam etching (IBE) is performed on the noble metal layer 4, and ion beam etching or reactive ion etching is performed on the first hard mask layer 3, so as to transfer the mask pattern to a surface of the second hard mask layer 2.

Optionally, after the reactive ion etching is performed on the first hard mask layer 3, the method may further include removing the photoresist 5.

In operation S230, the noble metal layer 4 is removed by corrosion, and ion beam etching or reactive ion etching is performed on the second hard mask layer 2, so as to transfer the mask pattern to a surface of the pattern-transfer target material.

In operation S240, the first hard mask layer 3 is removed by corrosion, and the pattern-transfer target material is etched according to the mask pattern.

In operation S250, the second hard mask layer 2 is removed by corrosion, and an etched product is cleaned to obtain a desired integrated circuit device.

As an example, when the first hard mask layer 3 is made of Si₃N₄ and the second hard mask layer 2 is made of SiO₂, both are resistant to an aqua-regia-like strong corrosive chemical liquid. In this case, the first hard mask layer 3, i.e., Si₃N₄, may be removed by corrosion with H₃PO₄ at 160° C., whereas SiO₂ has a very slow corrosion rate in this environment and may not be damaged.

As an example, when the first hard mask layer 3 is a silicon-rich anti-reflective layer (SiBACR) and the second hard mask layer 2 is a spin-on carbon (SOC) film, both are resistant to an aqua-regia-like strong corrosive chemical liquid. In this case, the first hard mask layer 3 may be removed by corrosion with diluted hydrogen fluoride (HF) at room temperature, whereas SOC has a very slow corrosion rate in this environment and may not be damaged.

As an example, when the first hard mask layer 3 is made of Poly Si (polysilicon) and the second hard mask layer 2 is made of SiO₂, both are resistant to an aqua-regia-like strong corrosive chemical liquid. In this case, Poly Si may be removed by corrosion with TMAH (tetramethylammonium hydroxide) at room temperature, whereas SiO is substantially not corroded in this environment.

In embodiments of the present disclosure, in a process of removing the first hard mask layer 3 by corrosion, a corrosion rate is less than 1 nm/min.

Through embodiments of the present disclosure, an accurate pattern transfer structure may be obtained, and damage of noble metal ions to devices may be avoided, so that noble metal films may be applied to large-scale integrated circuit manufacturing.

In addition, the terms “first” and “second” are used for descriptive purposes only and should not be understood as indicating or implying relative importance or implicitly indicating the quantity of the indicated technical features. Therefore, features defined by “first”. or “second” may explicitly or implicitly include one or more of such features. In the description of the present disclosure, “a plurality of” means at least two, such as two, three, etc., unless otherwise clearly and specifically defined. Furthermore, the word “a” or “an” preceding an element does not exclude the presence of a plurality of such elements.

The specific embodiments described above further illustrate the objectives, technical solutions and beneficial effects of the present disclosure. It should be understood that the above are merely specific embodiments of the present disclosure and not intended to limit the present disclosure. Any modifications, equivalent substitutions, improvements, etc. made within the spirit and principles of the present disclosure should be included in the scope of protection of the present disclosure.

1. A hard mask structure for integrated circuit manufacturing, comprising a first hard mask layer and a second hard mask layer stacked from top to bottom, wherein the first hard mask layer is configured to form a noble metal on a surface thereof and configured as a pattern-transfer sacrificial layer, and the second hard mask layer is configured as a protective layer and configured to etch a pattern-transfer target material;
wherein the first hard mask layer and the second hard mask layer are made of different materials and are resistant to a corrosion of a strong oxidizing chemical liquid applied for removing the noble metal;
wherein the second hard mask layer is resistant to a corrosion of a chemical liquid applied for removing the first hard mask layer by wet corrosion, and the second hard mask layer has a predetermined corrosion rate selectivity ratio to the first hard mask layer; and
wherein the noble metal comprises one or a combination of thin films selected from gold, silver, ruthenium, rhodium, palladium, osmium, iridium, or platinum.

2. The hard mask structure for integrated circuit manufacturing according to claim 1, wherein the first hard mask layer and the second hard mask layer constitute a dual hard mask set, and the hard mask structure comprises a plurality of dual hard mask sets stacked in sequence.

3. The hard mask structure for integrated circuit manufacturing according to claim 1,
wherein the first hard mask layer is made of a non-metallic dielectric material selected from at least one of silicon, silicon oxide, silicon nitride, polysilicon, amorphous silicon, silicon oxynitride, boron or phosphorus doped silicon oxide, silicon carbide, gallium nitride, indium phosphide, aluminum oxide, or titanium nitride; or
wherein the first hard mask layer is made of an organic material selected from a spin-on carbon film, an amorphous carbon film, a silicon-rich anti-reflective layer, or a carbon-rich anti-reflective layer.

4. The hard mask structure for integrated circuit manufacturing according to claim 1,
wherein the second hard mask layer is made of a non-metallic dielectric material selected from at least one of silicon, silicon oxide, silicon nitride, polysilicon, amorphous silicon, silicon oxynitride, boron or phosphorus doped silicon oxide, silicon carbide, gallium nitride, indium phosphide, aluminum oxide, or titanium nitride; or
wherein the second hard mask layer is made of an organic material selected from a spin-on carbon film, an amorphous carbon film, a silicon-rich anti-reflective layer, or a carbon-rich anti-reflective layer.

5. The hard mask structure for integrated circuit manufacturing according to claim 1,
wherein the strong oxidizing chemical liquid comprises aqua regia; or wherein the strong oxidizing chemical liquid contains high-purity HCl, high-purity HNO₃, and H₂O in a ratio of (0˜1):(0˜1):(0˜1).

6. The hard mask structure for integrated circuit manufacturing according to claim 1, wherein the first hard mask layer and the second hard mask layer are a combination of two thin films made of different materials, selected from:
the first hard mask layer being made of Si₃N₄ and the second hard mask layer being made of SiO₂;
the first hard mask layer being a silicon-rich anti-reflective layer and the second hard mask layer being a spin-on carbon film; or
the first hard mask layer being made of polysilicon and the second hard mask layer being made of SiO₂.

7. A method for manufacturing an integrated circuit device using the hard mask structure for integrated circuit manufacturing of claim 1, comprising:
forming a second hard mask layer, a first hard mask layer and a noble metal layer sequentially on a pattern-transfer target material, coating a photoresist on a surface of the noble metal layer, and performing photolithography to form a mask pattern;
performing ion beam etching on the noble metal layer, and performing ion beam etching or reactive ion etching on the first hard mask layer, so as to transfer the mask pattern to a surface of the second hard mask layer;
removing the noble metal layer by corrosion, and performing ion beam etching or reactive ion etching on the second hard mask layer, so as to transfer the mask pattern to a surface of the pattern-transfer target material;
removing the first hard mask layer by corrosion, and etching the pattern-transfer target material according to the mask pattern; and
removing the second hard mask layer by corrosion, and cleaning an etched product to obtain a desired integrated circuit device.

8. The method for manufacturing the integrated circuit device according to claim 7, further comprising: after performing the reactive ion etching on the first hard mask layer, removing the photoresist.

9. The method for manufacturing the integrated circuit device according to claim 7, wherein the removing the first hard mask layer by corrosion comprises any selected from:
removing the first hard mask layer by corrosion with H₃PO₄ at 160° C. in a case that the first hard mask layer is made of Si₃N₄ and the second hard mask layer is made of SiO₂;
removing the first hard mask layer by corrosion with diluted hydrogen fluoride at room temperature in a case that the first hard mask layer is a silicon-rich anti-reflective layer and the second hard mask layer is a spin-on carbon film; or removing the first hard mask layer by corrosion with tetramethylammonium hydroxide at room temperature in a case that the first hard mask layer is made of polysilicon and the second hard mask layer is made of SiO₂.

10. The method for manufacturing the integrated circuit device according to claim 7, wherein a corrosion rate is less than 1 nm/min in a process of removing the first hard mask layer by corrosion.
